(19) United States
(12) Patent Application Publication
(10) Pub. No.: US 2021/0125869 A1
(43) Pub. Date: Apr. 29, 2021

(54) SINGULATED SUBSTRATES FOR ELECTRONIC PACKAGING AND OTHER APPLICATIONS IN A ROLL FORMAT

(71) Applicant: CORNING INCORPORATED, CORNING, NY (US)

(72) Inventor: Nagaraja Shashidhar, Painted Post, NY (US)

(21) Appl. No.: 16/965,364

(22) PCT Filed: Jan. 31, 2019
(86) PCT No.: PCT/US2019/016181

§ 371 Date: Jul. 28, 2020

Related U.S. Application Data
(60) Provisional application No. 62/625,023, filed on Feb. 1, 2018.

(51) Int. Cl. H01L 21/78; H01L 21/02; H01L 21/683; H01L 23/14; H01L 23/48; H01L 21/56; H01L 23/31; H01L 23/498

(52) U.S. Cl. CPC H01L 21/78; H01L 21/02376; H01L 21/6836; H01L 21/0242; H01L 23/4985; H01L 23/145; H01L 23/481; H01L 21/56; H01L 23/3157; H01L 21/02499

(57) ABSTRACT

Embodiments of the disclosure relate to a method for creating a strip of electronic components. In the method, a ribbon of ceramic substrate is provided. The ceramic substrate defines a thickness of no more than 200 μm between a first outer surface and a second outer surface opposite of the first outer surface. A conductive layer is applied to at least one of the first outer surface or the second outer surface of the ceramic substrate. The ceramic substrate is then singulated into individual slabs, and the individual slabs are laminated to a strip of polymeric carrier. The polymeric carrier has a flexural rigidity less than the flexural rigidity of the ceramic substrate. Additionally, embodiments of a roll of electronic components are provided.

### CROSS-REFERENCE TO RELATED APPLICATIONS

This application claims the benefit of priority of U.S. Provisional Application Ser. No. 62/625,023 filed on Feb. 1, 2018 the contents of which are replied upon and incorporated herein by reference in their entirety.

### BACKGROUND

The disclosure relates generally to a method for fabricating electronic components and, in particular, to a method of producing a strip of electronic components in a roll-to-roll format. Individual electronic components having a polymeric substrate are often formed as part of a large group contained on a wafer, typically having a size in the range of 200 mm to 300 mm. The group of electronic components comprising the wafer is then diced into the individual electronic components. In applications requiring a large number of electronic components, the electronic components are attached to a rolled strip for ease of dispensing at the consumer end. However, creating electronic components from wafers is a batch process, whereas attaching them to a strip is generally a continuous process. Because of the difference in processing techniques and speeds, disruptions in the overall process often arise.

### SUMMARY

In one aspect, embodiments of the disclosure relate to a method for creating a strip of electronic components. In the method, a ribbon of ceramic substrate is provided. The ceramic substrate defines a thickness of no more than 200 μm between a first outer surface and a second outer surface opposite of the first outer surface. A conductive layer is applied to at least one of the first outer surface or the second outer surface of the ceramic substrate. The ceramic substrate is then singulated into individual slabs, and the individual slabs are laminated to a strip of polymeric carrier. The polymeric carrier has a flexural rigidity less than the flexural rigidity of the ceramic substrate.

In another aspect, embodiments of the disclosure relate to a roll of electronic components. The strip includes a plurality of electronic components in which each of the electronic components includes a ceramic substrate. The strip also includes a strip of polymeric carrier. The plurality of electronic components is adhered to a surface of the strip of polymeric carrier. Each ceramic substrate has a first thickness and a first flexural rigidity, and the strip of polymeric carrier has a second thickness and a second flexural rigidity. The first thickness is less than the second thickness, and the first flexural rigidity is at least five times the second flexural rigidity.

Additional features and advantages will be set forth in the detailed description that follows, and, in part, will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding and are incorporated in and constitute a part of this specification. The drawings illustrate one or more embodiment(s), and together with the description serve to explain principles and the operation of the various embodiments.

### BRIEF DESCRIPTION OF THE DRAWINGS

FIG. 1 is a strip of slabs for electronic components produced from a roll-to-roll fabrication method, according to an exemplary embodiment.

FIG. 2 is a top view of the strip of FIG. 1, according to an exemplary embodiment.

FIG. 3 is a flow diagram of a first roll-to-roll fabrication method for preparing the strip of slabs for electronic components, according to an exemplary embodiment.

FIG. 4 is a flow diagram of second roll-to-roll fabrication method for preparing the strip of slabs for electronic components, according to an exemplary embodiment.

FIG. 5 is a light emitting diode formed from a roll-to-roll fabrication method, according to an exemplary embodiment.

FIG. 6A is top view of a slab heater produced via a roll-to-roll fabrication method, according to an exemplary embodiment.

FIG. 6B is a side view of the slab heater of FIG. 6A with the addition of a dielectric element, according to an exemplary embodiment.

FIG. 7 is a chip resistor formed from a roll-to-roll fabrication method, according to an exemplary embodiment.

FIG. 8A is a multi-layer capacitor with the layers connected in series formed from a roll-to-roll fabrication method, according to an exemplary embodiment.

FIG. 8B is a multi-layer capacitor with the layers connected in parallel formed from a roll-to-roll fabrication method, according to an exemplary embodiment.

FIG. 9 depicts slabs being separated from the carrier as the carrier travels over a roller, according to an exemplary embodiment.

FIG. 10 depicts a strip having tracks configured to follow a sprocket for precision movement of the strip during processing, according to an exemplary embodiment.

### DETAILED DESCRIPTION

Embodiments of the present disclosure relate to a method of preparing strips of singulated electronic components. In particular embodiments, the method is performed in a roll-to-roll fashion. That is, each fabrication step is performed in continuous and sequential steps from an initial roll of raw material, such as a ribbon of ceramic substrate, to the final singulated electronic components attached to a strip and rolled on a spool that is delivered to the customer. The roll-to-roll fabrication method has the potential to reduce the packaging cost for certain electronic components, especially electronic components that conventionally utilize polymeric substrates, such as printed circuit board. In particular, the roll-to-roll fabrication method eliminates the need to dice large wafers of electronic components produced in batches. A variety of embodiments of the method and electronic components produced according to the method are provided herein. These embodiments are presented by way of example only and not by way of limitation.

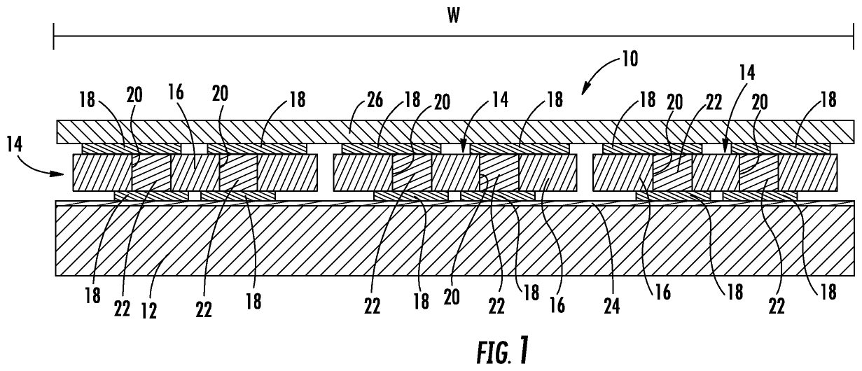

In order to introduce the processing steps, a completed electronic component mounted on a carrier will be described first. In particular, FIG. 1 depicts a strip 10 including a carrier 12 on which several slabs 14 are mounted. As used herein, a “slab” refers to a singulated, thin ceramic material. Such slabs may include functional additions, such as conductive circuit patterns, resistors, capacitors, etc., deposited on one or both sides the ceramic material. In general, such slabs are less than 200 μm in thickness, have a length of less than 100 mm, and have a width less than 100 mm. The slabs 14 consist of a ceramic substrate 16 having a conductive layer 18 disposed on the top and/or bottom sides of the ceramic substrate 16. In embodiments, the conductive layers 18 are connected using vias 20 that are filled with a conductive material 22. Thus, in embodiments, the conductive layer 18 on the top side of the ceramic substrate 16 is in electrical communication with the conductive layer 18 on the bottom side of the ceramic substrate 16. The slabs 14 are attached to the carrier 12 with temporary adhesive 24. In certain embodiments, the slabs 14 are covered with a protective film 26.

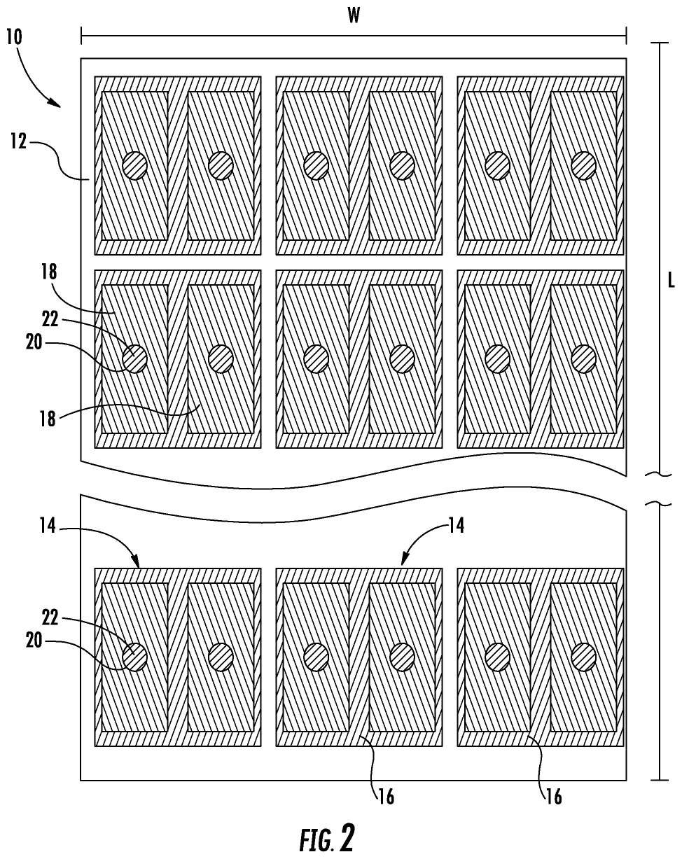

As can be seen in FIG. 2, which depicts a top view of the strip 10 (without the protective film 26), the slabs 14 are arranged along the length L of the carrier 12. In embodiments, the length L is several meters or hundreds of meters. For example, the length L can be at least 10 m long, at least 50 m long, or at least 100 m long, and further, in embodiments, the length L can be up to 500 m long. Multiple slabs 14 can also be positioned across the width W of the carrier 12 (as is shown also in FIG. 1). In embodiments, the width W is at least 25 mm wide, and in embodiments, the width W is up to 48 mm wide, up to 75 mm wide, up to 100 mm wide, or up to 150 mm wide. In a particular embodiment, the width W of the carrier 12 is 80 mm wide. The slabs 14 on the carrier 12 are spaced from each other by a predetermined amount. In embodiments, the predetermined amount of space is 0.1 mm. Taking as an example a carrier 12 with a width of 25 mm, a slab 14 having a length and width of 1.2 mm, and a spacing of 0.1 mm between slabs 14, the strip 10 will have 14,611 slabs per meter (19 slabs across the width×769 along the length=14,611 slabs). Thus, a strip 10 that is 100 m in length can hold 1.46 million slabs.

The number of slabs 14 that a strip 10 can hold is dependent on the size of the slabs 14. Further, the size can vary widely depending on a particular application, and therefore, the slabs 14 can be quantified in lot sizes. On the strip 10, a marking can be made to demarcate each lot of slabs 14, which allows easier tracking of production. Table 1, below, provides exemplary lot sizes for strips 10 of various sizes that contain slabs 14 of various types.

TABLE 1
Exemplary Slabs on Strip Configurations

| | Strip 1 | Strip 2 | Strip 3 | Strip 4 |
|---|---|---|---|---|
| Width of carrier (mm) | 25 | 25 | 80 | 150 |
| Length of slab (mm) | 0.8 | 1.2 | 5 | 20 |
| Width of slab (mm) | 0.8 | 2.2 | 5 | 20 |
| Spacing (mm) | 0.1 | 0.1 | 0.1 | 0.1 |
| # slabs along | 25 | 18 | 15 | 7 |
| width | | | | |
| # slabs along | 1111 | 434 | 196 | 49 |
| 1 m length | | | | |
| # slabs per | 27775 | 7812 | 2940 | 343 |
| m lengths | | | | |
| # slabs per | 2.7775 | 0.7812 | 0.294 | 0.0343 |
| 100 m (in millions) | | | | |
| Lot quantity | 25000 | 5000 | 2500 | 250 |
| Length of tape per | 900 | 638.9 | 850.0 | 717.9 |
| lot (mm) | | | | |
| Example Component | LED | Chip | Capacitors | Heaters |
| | | resistor | | |

Having described the components of the strip 10, embodiments of methods for constructing the strip are now provided. In particular embodiments, the strip 10 is constructed in a “roll-to-roll” format on a single process line; that is, the slab 14 is constructed and attached to the carrier 12 in a continuous process beginning with a ribbon of ceramic substrate 16 and ending with a roll of the finished strip 10. However, in other embodiments, the method is not continuous, and certain steps of the method can be carried out across two or more process lines.

As mentioned, the method begins with constructing the slab 14 from a ribbon of ceramic substrate 16. In embodiments, the ceramic substrate 16 is sintered alumina, partially-stabilized or fully-stabilized zirconia, titanates (especially for capacitor applications), ferrites (especially for applications involving magnetic shielding), or another ceramic material. It should be noted that, during fabrication, multiple slabs 14 can be formed across the width of the ceramic substrate 16 as well as along the length of the ceramic substrate 16. As will be discussed below, individual slabs 14 are singulated from the ribbon of ceramic substrate 16. In embodiments, the ribbon of ceramic substrate 16 has a thickness of no more than 200 μm. In another embodiment, the ribbon of ceramic substrate 16 has a thickness of no more than 100 μm, and in still another embodiment, the ribbon of ceramic substrate 16 has a thickness of at least 10 μm. In a particular embodiment, the ceramic substrate 16 has a thickness of 40 μm.

In embodiments of a method 100, such as the embodiment shown in the flow diagram of FIG. 3, vias 20 are formed in the ceramic substrate 16 in a first step 101. In embodiments, the vias 20 are formed using a laser ablation process. In certain embodiments, the laser ablation process uses nanosecond or faster laser pulses, which provides clean (i.e., smooth surfaced) holes and which does not have a significant impact on the strength of the ceramic substrate 16. After forming the vias 20, the ceramic substrate can optionally be coated with an adhesion layer (not shown). The adhesion layer is a thin layer (e.g., from 100 nm to 500 nm in thickness) that helps to adhere the conductive layer 18 to the ceramic substrate 16. In embodiments, the adhesion layer is one of titanium, tungsten, titanium-tungsten alloys, titanium nitride, tantalum, tantalum nitride, chromium, or chrome-copper alloy. In this optional second step 102, the adhesion layer can be applied using a continuous sputtering process in which the ceramic substrate 16 is run through a sputtering chamber in which the top and/or bottom side of the ceramic substrate 16 is sputter-coated with adhesion layer. If the optional step 102 of applying the adhesion layer is performed, the vias 20 are sized so as to account for the conformal coating of the adhesion material (e.g., sized so as to wick solder into the vias 20 during reflow soldering).

In a third step 103, the conductive layer 18 or conductive layers 18 are plated onto the ceramic substrate 16 (or adhesion layer, if applied). In embodiments, the conductive layers 18 are selected to be at least one of copper, silver, or nickel, and in embodiments, the thicknesses of the conductive layers 18 are from 2 μm to 20 μm in thickness. In a particular embodiment, the conductive layers 18 are formed from copper and have a thickness of 10 μm to 12 μm. In embodiments, the conductive layers 18 are applied by electroplating the copper onto the ceramic substrate 16 (or adhesion layer). After the third step 103 of electroplating with copper, the copper plating is then covered with a mask in the portions defining a circuit pattern for the conductive layer 18, and in a fourth step 104, an etchant is applied to dissolve the regions of the copper plate outside of the circuit pattern. The mask is then removed. In embodiments, the mask is applied by laminating a dry film over the ceramic substrate 16 or adhesion layer and then exposing the dry film to ultraviolet light to create the circuit pattern. After electroplating, removal of the mask can be accomplished using a caustic solution. In an alternate embodiment, the mask is applied prior to electroplating such that copper is only applied in regions defining the circuit pattern.

After the fourth step 104, soldering pads (not shown) are formed on or adjacent to the conductive layers 18 in a fifth step 105. In embodiments, another dry film mask is applied over the surface of the plated ceramic substrate 16 to define open regions where the soldering pads are to be located. In embodiments, nickel and/or gold is deposited in the open regions to form the soldering pads. In certain embodiments, the soldering pads are formed through electroless plating. Further, in embodiments, the steps 103, 104, 105 are repeated as necessary to provide one or more layers of conductive layer 18 on one or both sides of the ceramic substrate 16.

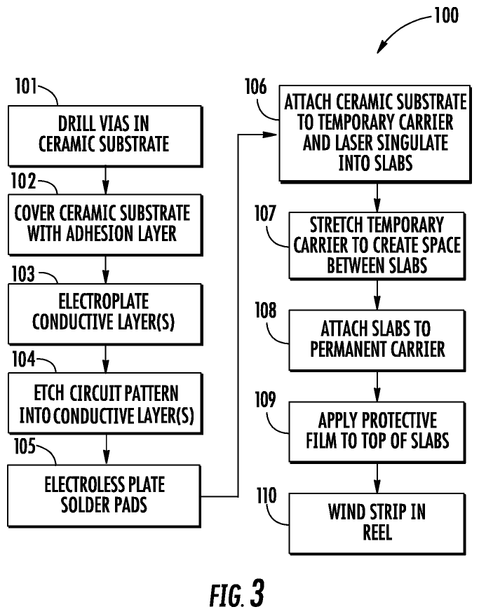

In an alternate embodiment that is shown in the flow diagram of FIG. 4, thick film techniques are utilized instead of the thin film sputtering and plating technologies described previously. As with the embodiment of FIG. 3, the method of FIG. 4 begins with a first step 201 of drilling vias 20 into the ceramic substrate 16. Thereafter, in a second step 202, functional layers, such as the conductive layers 18, are printed on a first side of the ceramic substrate 16 using a roll-to-roll printing technique, such as Gravure printing, ink-jet printing, flexographic printing, or imprint lithography, among others. During the second step 202, the functional layers are also sintered into dry, solid layers. The second step 202 can be repeated as necessary to build a layered structure on the first side of the ceramic substrate 16. Thereafter, in an optional third step 203, a functional layer can be printed and sintered onto a second side of the ceramic substrate 16. As with the second step 202, the third step 203 can be repeated as necessary to build a layered structure on the second side of the ceramic substrate 16. Further, the steps 202, 203 can be performed in an alternating manner. In such embodiments, functional layers on both sides of the ceramic substrate 16 are able to be sintered in a single step.

Advantageously, through printing on the ceramic substrate 16, components having various functionalities are able to be formed on the ceramic substrate. For example, the printing technique can be used to apply various functional layers, such as conductive layers 18, resistors, multilayers of conductive circuitry separated by dielectric layers, piezo-resistors, potentiometer resistors, heater resistors, and/or NTC (negative temperature coefficient) thermistors, among others. In embodiments, up to twenty layers can be applied to one or more sides of the ceramic substrate 16. As with the previous embodiment, solder pads are also deposited in a fourth step 204 to provide connection points.

After forming the soldering pads in step 105 of FIG. 3 or step 204 of FIG. 4, the slabs 14 have essentially been constructed and only need to be singulated into individual components. In order to facilitate singulation, a temporary carrier (not shown) is laminated to the ribbon of ceramic substrate 16 (step 106 of FIG. 3; step 205 of FIG. 4). A laser then singulates the ribbon of ceramic substrate 16 into individual slabs 14 that are held together by the temporary carrier. In an embodiment, the temporary carrier is polyethylene terephthalate (PET), polyester, or another similar polymeric film, for example, with an adhesive surface for holding the slabs 14. In step 107 of FIG. 3 or step 206 of FIG. 4, the temporary carrier is then stretched across its width and length (e.g., in a draw and tenter process) to create space between the laser-singulated slabs 14.

In step 108 of FIG. 3 or step 207 of FIG. 4, the spaced slabs 14 are then laminated to the carrier 12. In embodiments, the carrier 12 is a flexible substrate made of a polymer, such as polyimide, PET, or polyethylene naphthalate (PEN). In another embodiment, the carrier 12 is a ribbon of metal, such as aluminum, stainless steel, or other metals. In embodiments, the carrier 12 has a thickness of at least 25 μm, and in other embodiments, the carrier 12 has a thickness of at least 50 μm. In embodiments, the carrier 12 has a thickness of up to 125 μm. As mentioned above, the width W of the carrier 12 is from 25 to 150 mm. In a specific embodiment, the thickness is 40 μm, and the width W is 25 mm, and the length L is at least 100 m.

In order to laminate the slabs 14 to the carrier 12, the adhesive 24 is sprayed, coated, deposited, or otherwise applied to the slabs 14 and/or to the carrier 12. Exemplary methods for applying the adhesive include slot die coating, printing, chemical vapor deposition, or physical vapor deposition. In embodiments, non-limiting examples of the adhesive 24 include at least one of an epoxy, silicone rubber, polyimide, phenylenebenzobisoxazole (PBO), or benzocyclobutene (BCB). In embodiments, the adhesive 24 and the carrier 12 are selected for their ability to maintain their properties throughout various operations. For example, the adhesive 24 and carrier 12 should be able to withstand reflow soldering temperatures (e.g., up to 250° C.) and curing cycles (e.g., up to 150° C.) without losing adhesive strength or substantially degrading in mechanical properties, respectively.

Further, because the slabs 14 are intended to be removable from the carrier 12 so as to facilitate use of the slab 14 in an electronic component, the adhesive 24 is selected such that it is strong enough to hold the slab 14 securely to the carrier 12 but not so strong as to make removal difficult for a user. In a particular embodiment, adhesion strength of the slab 14 to the carrier 12 is at least 1.6 N/cm as characterized by the 90° peel test as defined by ASTM D6862. In particular, the adhesion strength reduces to less than 0.5 N/cm at the time of debonding. As will be discussed more fully below, the reduction in adhesion strength for debonding can be accomplished through heating the tape to a high temperature; applying local ultrasonic energy, applying photo excitation (e.g., ultraviolet radiation), chemical activation or solvent swelling, or laser activation, among other means.

After laminating the slabs 14 to the carrier 12, in embodiments, the slabs 14 are covered by the protective film 26 (step 109 of FIG. 3 or step 208 of FIG. 4). In embodiments, the protective film 26 is a polymer, such as PET. Further, in embodiments, the protective film 26 has a thickness of from 12.5 μm to 100 μm. In a more particular embodiment, the protective film 26 has a thickness of 25 μm. The protective film 26 is configured to be peeled off of the slabs 14 prior to use. After covering with the protective film 26, the strip 10 is wound onto a reel (step 110 of FIG. 3 or step 209 of FIG. 4).

Having described an embodiment of the method for producing electronic components in a roll-to-roll format, certain attributes that contribute to the effectiveness of the overall method are now discussed. These attributes contribute to the overall efficiency of the method as well as to the quality of the final product.

In certain circumstances, the strip 10, which, in embodiments, is provided in a roll, may be transported over various rollers during subsequent operations, such as during surface mounting of components onto the ceramic substrate 16. In such instances, a peeling stress may develop when the flexural rigidities of the ceramic substrate 16 and the carrier 12 are different. The magnitude of the peeling stress developed is a function of the radius of curvature over which the strip 10 travels. A larger radius of curvature will develop lower peel stress than a smaller radius of curvature. The magnitude of the peeling stress is also dependent on the differences in the flexural rigidities between the ceramic substrate 16 and the carrier 12. Flexural rigidity of a material is defined by the following formula:

$$D = E \frac{{d}^{3}}{12 ( 1 - {v}^{2} )}$$

where D is the flexural rigidity, E is the Young's modulus, d is the thickness of the layer, and v is Poisson's ratio. A higher difference in the flexural rigidities of the ceramic substrate 16 and the carrier 12 will lead to higher peeling stress. If the peeling stress exceeds the adhesive strength of the temporary adhesive layer 24, the ceramic substrate 16 (or completed slab 14) may delaminate from the carrier 12. Such delamination can be avoided by selecting an adhesive that has a high enough peeling stress for the particular application. However, in circumstances where selecting such an adhesive is not possible, then delamination can be avoided by lowering the difference between the flexural rigidities of the ceramic substrate 16 and the carrier 12 or by increasing the radius of curvature for the rollers over which the strip 10 travels.

Further, in embodiments, thickness of the ceramic substrate 16 is selected to be less than the thickness of the carrier 12. In doing so, the carrier 12 is able to be handled more efficiently because there is uniform stress on the carrier 12 when it undergoes the web-handling process. Second, in embodiments, the elastic modulus of the slabs 14 should be high so that circuits with fine lines and spaces can be patterned on the substrate. Third, in embodiments, the ceramic substrate 16 is designed so as to have a flexural rigidity of at least five times greater than the flexural rigidity of the carrier 12. In further embodiments, the flexural rigidity of the ceramic substrate 16 is at least ten times greater than that of the carrier 12, and in still further embodiments, the flexural rigidity of the ceramic substrate 16 is at least twenty times greater that of the carrier 12.

The third attribute, in particular, enhances the ability to handle the slabs while in a roll. In particular, it is difficult to handle the slabs 14 and separate them from the carrier 12 unless the ceramic substrate 16 of the slab 14 is rigid. Table 2, below, provides the flexural rigidity of an alumina ceramic substrate 16 as compared to a conventional polyimide substrate. Table 1 also provides the rigidity ratio of the ceramic substrate 16 to the carrier 12 for polyimide carriers 12 of different thickness.

TABLE 2
Flexural Rigidity Properties of Slab and Carrier Materials

| | | | Elastic | Poisson's | | |
|---|---|---|---|---|---|---|
| | | Thickness | modulus | ratio | Rigidity | Rigidity ratio |
| | Role | (μm) | (GPa) | (unitless) | (Pa-m³) | substrate/carrier |
| Alumina | Substrate | 40 | 380 | 0.21 | 2.03 × 10¹⁸ | — |
| Polyimide | Substrate | 205 | 2.5 | 0.34 | 2.01 × 10¹⁸ | — |
| Polyimide | Carrier | 50 | 2.5 | 0.34 | 2.84 × 10¹⁶ | 71.3 |
| Polyimide | Carrier | 75 | 2.5 | 0.34 | 9.70 × 10¹⁶ | 20.9 |
| Polyimide | Carrier | 100 | 2.5 | 0.34 | 2.31 × 10¹⁷ | 8.8 |
| Polyimide | Carrier | 125 | 2.5 | 0.34 | 4.53 × 10¹⁷ | 4.5 |

As can be seen from Table 1, a 40 μm alumina ceramic substrate 16 has approximately the same flexural rigidity as a much thicker polyimide substrate (205 μm). In particular, the thickness and the flexural rigidity of the ceramic substrate 16 enable the ceramic substrate 16 to undergo subsequent component mounting processes and module handling processes after being separated from the carrier 12.

Table 3, below, provides instances in which the thickness of the carrier 12 is manipulated such that the carrier 12 has the same flexural rigidity as the ceramic substrate 16. As can be seen in Table 3, to achieve the same flexural rigidity as an alumina ceramic substrate 16 with a thickness of 40 μm (i.e., a rigidity ratio of 1), a carrier 12 of polyimide would have to be 205 μm thick, a carrier 12 of aluminum 6061 would have to be 68 μm thick, and a carrier 12 of stainless steel 304 would have to be 50 μm thick. If the rigidity ratio is raised to 5, the thicknesses of these materials can be much lower. As discussed above, however, the thickness of the ceramic substrate 16 is thinner than the thickness of the carrier 12 in embodiments to facilitate subsequent handling and processing of the strip 10.

TABLE 3
Thickness of Carrier Materials and Associated Rigidity Ratios

| | | | Elastic | Poisson | | |
|---|---|---|---|---|---|---|
| | | Thickness | modulus | ratio | Rigidity | Rigidity ratio |
| | Role | μm | GPa | (unitless) | Pa-m³ | substrate/carrier |
| Alumina | Substrate | 40 | 380 | 0.21 | 2.03 × 10¹⁸ | — |
| Polyimide | Carrier | 120.4 | 2.5 | 0.34 | 4.05 × 10¹⁷ | 5.0 |
| Polyimide | Carrier | 205.5 | 2.5 | 0.34 | 2.03 × 10¹⁸ | 1.0 |
| Aluminum 6061 | Carrier | 25.0 | 68.9 | 0.33 | 9.36 × 10¹⁶ | 21.6 |
| Aluminum 6061 | Carrier | 40.4 | 68.9 | 0.33 | 4.05 × 10¹⁷ | 5.0 |
| Aluminum 6061 | Carrier | 68.6 | 68.9 | 0.33 | 2.03 × 10¹⁸ | 1.0 |
| Stainless steel 304 | Carrier | 25.0 | 190 | 0.265 | 2.47 × 10¹⁷ | 8.2 |
| Stainless steel 304 | Carrier | 29.4 | 190 | 0.265 | 4.05 × 10¹⁷ | 5.0 |
| Stainless steel 304 | Carrier | 49.8 | 190 | 0.265 | 2.03 × 10¹⁸ | 1.0 |

A particular embodiment of the strip 10 is now described. In this embodiment, the carrier 12 is a flexible polymer with a thickness of 75 μm. A layer of adhesive 24 is applied to the carrier 12 and has a thickness of 6 μm. The slabs 14 each include a ceramic substrate 16 with a thickness of 40 μm and conductive layers 18 on both the top and bottom sides with the conductive layers 18 being 10 μm thick. The slabs 14 are covered with a protective film 26 having a thickness of 25 μm. Accordingly, the strip 10 has a total thickness of 166 μm. A standard reel that is used in packaging electronic components in a tape-on-reel system has a hub diameter of 150 mm and outer diameter of 330 mm. Using the aforedescribed strip 10 and the standard reel, 400 m of strip 10 can be stored on the reel, which facilitates low-cost mass production of electronic components. Indeed, as demonstrated above in Table 1, several million slabs 14 can be provided on a strip 10 that is 400 m long (depending, in part, on the particular type of electronic component).

In the remaining figures, embodiments of electronic components that are capable of being fabricated using the above-described roll-to-roll method are provided. In FIG. 5, the slab 14 is formed into a light emitting diode (LED) chip 27. In particular, an LED 28 is mounted to the conductive layer 18 on the top side of the slab 14. Further, a phosphor 30 is coated on the LED 28 to provide light of a specific color or colors. In embodiments, the LED chip 27 is formed during the roll-to-roll fabrication method after the step of electroless plating the solder pads or after the step of singulating the slabs 14. In other embodiments, the finished reel of strip 10 is used to create the LED chips on a separate process line. In either embodiment, the LED chips can advantageously be tested for LED performance on-line. The strip 10, including the LED chips 27, can then shipped to the customer, who detaches the module when assembling products like luminaires. Further, because the strip 10 uses a slab 14 with a ceramic substrate 16, the slab 14 is better able to withstand the heat generated from high-powered LED packages.

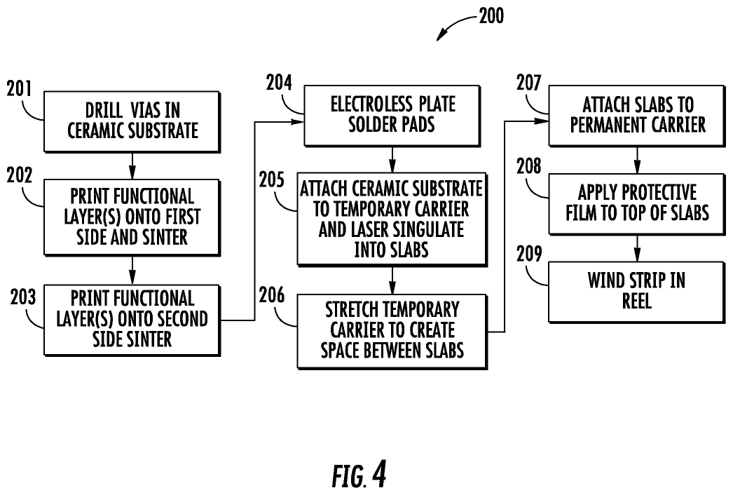

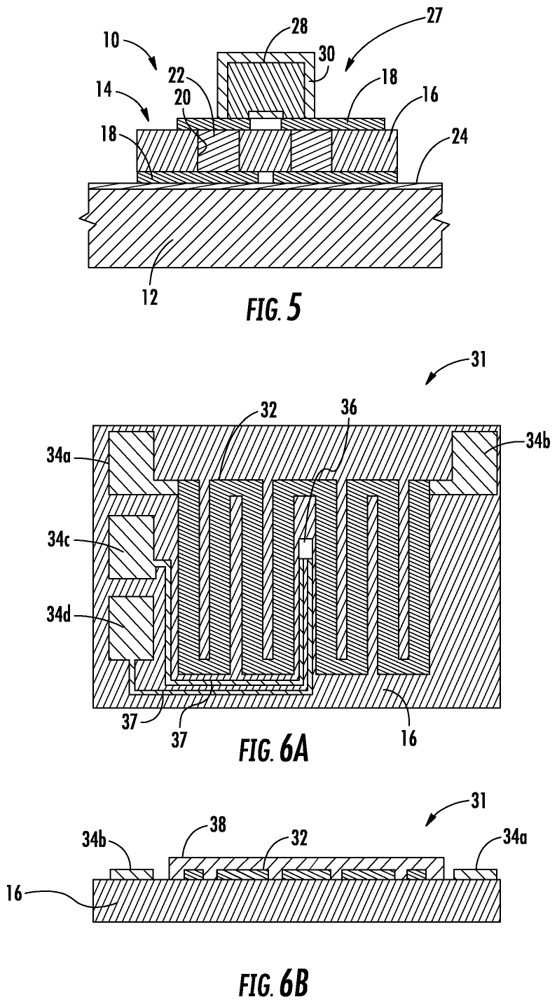

In FIG. 6A, the slab 14 is a heater 31. In particular, a resistive heating element 32 is deposited on the ceramic substrate 16. As shown in FIG. 6A, the resistive heating element 32 has a serpentine shape with conductive elements 34a, 34b at each end. A sensor 36, such as an NTR thermistor, is provided near the center of the top surface of the ceramic substrate 16. Two additional conductive elements 34c, 34d are provided along with conductive traces 37 to provide for electrical communication with the sensor 36. As shown in FIG. 6B, the resistive heating element 32 and sensor 36 are covered by a dielectric layer 38. However, in other embodiments, the sensor 36 can be positioned in a different plane from the resistive heating element 32 and/or separated from the resistive heating element 32 by the dielectric layer 38.

FIG. 7 provides an embodiment of the slab 14 as a chip resistor 39. Conductive strips 40 are deposited on the top and bottom surface of the ceramic substrate 16. The conductive strips 40 are connected by vias 20 filled with conductive material 22. On the top surface of the ceramic substrate 16, a resistive element 42 is deposited between the conductive strips 40. Further, a dielectric layer 38 is deposited on top of the resistive element 42. Further, in embodiments, a value 44 of the resistive element 42 is printed on the dielectric layer 32. As shown in FIG. 7, the resistor value 44 is 47Ω. Advantageously, the chip resistor 39 as shown and described has a low height profile. In a particular embodiment, the conductive strips 40, resistive element 42, dielectric layer 38, and resistor value 44 are all printed on the ceramic substrate 16 (e.g., as discussed above with respect to FIG. 4).

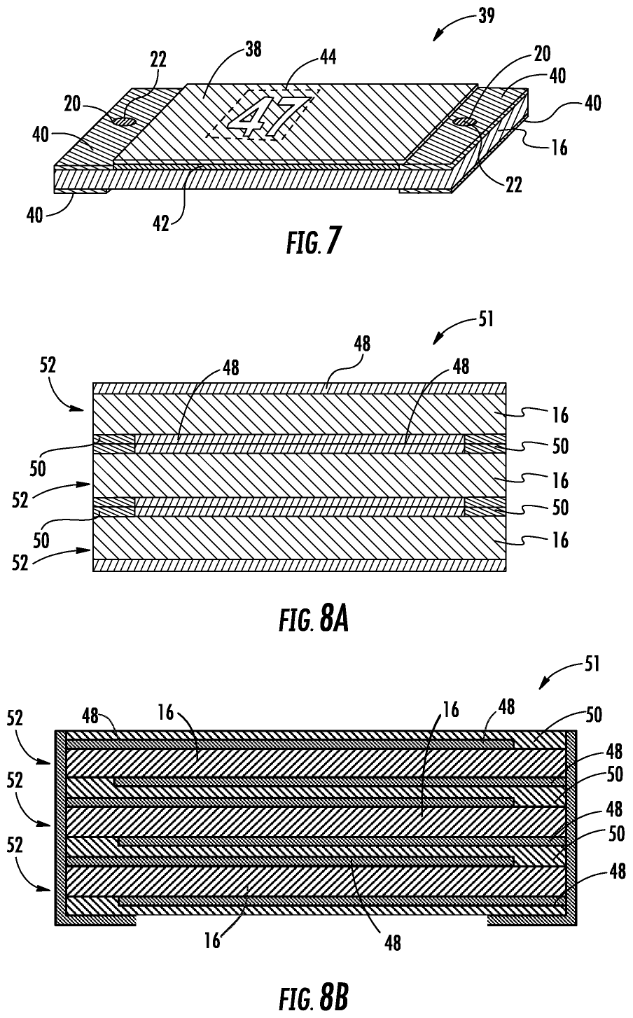

In FIG. 8A and FIG. 8B, multi-layer capacitors 51 are shown. In FIG. 8A, the ceramic substrates 16 have been screen printed with conducting layers 48 and insulating layers 50. The ceramic substrates 16 function as the dielectric material of individual capacitors 52 of the multi-layer capacitor 46. As can be seen, the conducting layers 48 and the insulating layers 50 are arranged in such a way as to join the capacitors 52 in series. In FIG. 8B, the conducting layers 48 and the insulating layers 50 of the multi-layer capacitor 51 are arranged in such a way as to join the capacitors 52 in parallel. Advantageously, as compared to conventional co-fired ceramic capacitors, the multi-layer capacitors 51 of this design can be made larger in size, higher in capacitance, and better able to withstand higher breakdown voltage.

In still other embodiments not depicted, additional complex circuit elements can be created. For example, the slab can include an antenna that is printed on the ceramic substrate. Resistors, inductors, capacitors, and other tunable elements can also be patterned on the ceramic substrate. The bottom side of the slab can include a conductive layer functioning as a ground plane. In other embodiments, the top side of the slab can have integrated circuits and other passive components mounted thereon. The slab can also contain printed sensors that sense, e.g., temperature, capacitance, pressure (piezoelectric), humidity, and/or gas.

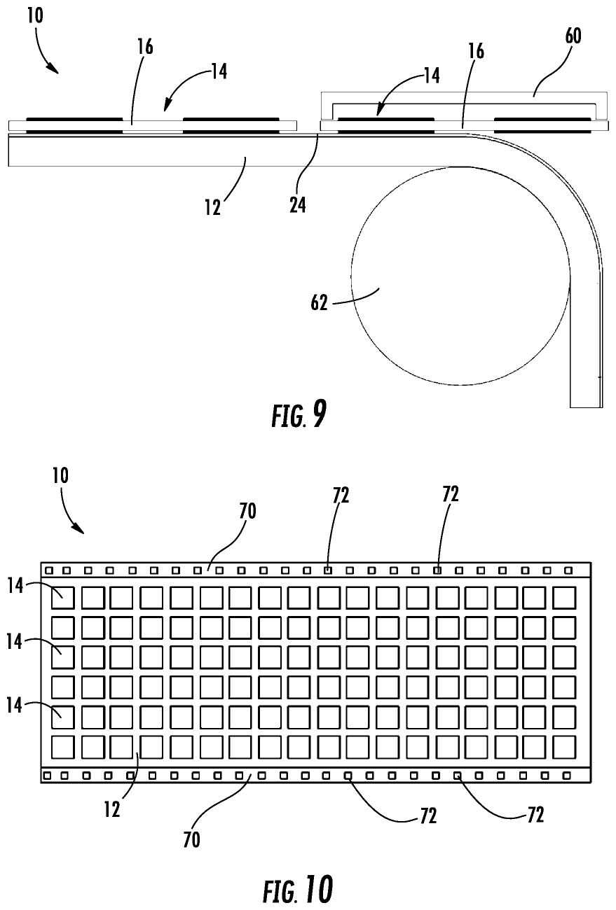

Referring to the slabs 14 as described above, FIG. 9 provides an exemplary embodiment of how the slabs 14 can be removed from the carrier 12. After all of the components have been mounted on the ceramic substrate 16, the finished slab 14 is held by a pick-up tool 60 from the top as the carrier 12 is bent over a roller 62. In such an embodiment, certain factors contribute to successful separation of the slab 14 from the carrier 12: the strength of the ceramic substrate 16, the bending stress in the ceramic substrate 16, and the peel force.

The strength of the ceramic substrate 16 is influenced by flaws and/or defects in the material that, in some circumstances, can be introduced during the fabrication process, such as during via drilling, metallization, singulation, or handling during component assembly. Such flaws and/or defects can be decreased by using high-speed lasers, such as femto-second lasers, during via drilling and singulation and by preventing the ceramic substrate 16 from contacting hard materials, such as other ceramics or metals, as it goes through various processing steps. For example, as shown in FIG. 10, the carrier 12 can be moved more precisely using a sprocket track 70 with holes 72 for engaging the teeth of a sprocket. In this way, the carrier 12 can move over a roller, such as roller 62 of FIG. 9, in a precise manner, reducing the likelihood that the strip 10 will be bumped or scraped against a hard component on the processing line. Additionally, such a sprocket track 70 is useful for precisely positioning the carrier 12 while electronic components are assembled on the slab 14.

The bending stress is influenced by the elastic modulus of the ceramic substrate 16, the thickness of the ceramic substrate 16, the size of the slab 14, and the speed at which the slab 14 is separated from the carrier 12. In general, a higher elastic modulus will lead to a higher magnitude of bending stress. Further, in general, a thinner ceramic substrate 16 will develop more bending stress than a thicker ceramic substrate 16 of the same material. Also, in general, a larger slabs and higher separation speeds will lead to a higher bending stress. By taking into account the elastic modulus of the ceramic substrate 16, the thickness of the ceramic substrate 16, the size of the slabs 14, and the speed of separation, the bending stress can be managed so as to avoid exceeding the strength of the ceramic substrate 14.

With respect to the peel force, damage to the ceramic substrate 16 can be reduced by using an adhesive (high- or medium-tack) during the processing steps. However, in order to facilitate removal of the slabs 14 from the carrier 12, the adhesive can be weakened just prior to separation. For example, depending on the type of adhesive, the strip can be exposed to UV light, increased temperature, moisture, magnetic fields, ultrasonic energy, and/or electrostatic forces. In embodiments, the specific technique for weakening the adhesive minimizes or eliminates adhesive residue left behind on the slab 14 after separation. In embodiments, the adhesive strength, as measured by the 90° peel test defined in ASTM D6862, is greater than 4 N per 25 mm wide carrier and, after the weakening technique is performed, reduces to less than 0.4 N per 25 mm wide carrier.

Accordingly, manipulation and/or optimization of the strength of the ceramic substrate 16, the bending stress in the ceramic substrate 16, and the peel force can enhance the ability of the slabs 14 to separate from the carrier 12 when desired by the manufacturer or end user.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

What is claimed is:

1. A method for creating a strip of electronic components, the method comprising the steps of:
providing a ribbon of ceramic substrate, the ceramic substrate defining a thickness of no more than 200 μm between a first outer surface and a second outer surface opposite of the first outer surface;
applying a conductive layer to at least one of the first outer surface or the second outer surface of the ceramic substrate;
singluating the ceramic substrate into individual slabs; and
laminating the individual slabs to a strip of polymeric carrier, the polymeric carrier having a flexural rigidity less than the flexural rigidity of the ceramic substrate.

2. The method of claim 1, further comprising the step of depositing an adhesion layer prior to the step of applying the conductive layer.

3. The method of claim 2, wherein the adhesion layer has a thickness of from 100 nm to 500 nm.

4. The method of claim 2, wherein the adhesion layer comprises at least one of titanium, tungsten, titanium-tungsten alloys, titanium nitride, tantalum, tantalum nitride, chromium, or chrome-copper alloys.

5. The method of claim 1, further comprising the step of forming vias through the thickness of the ceramic substrate by laser ablating holes of from 25 μm to 125 μm through the thickness of the ceramic substrate.

6. The method of claim 1, further comprising the step of laminating a temporary carrier to the ceramic substrate prior to the step of singulating, wherein, during the step of singulating, the temporary carrier retains the individual slabs.

7. The method of claim 6, further comprising a step of stretching the temporary carrier after the singulating step so as to create a predefined space between the individual slabs.

8. The method of claim 1, further comprising the step winding the polymeric carrier into a roll after the laminating step.

9. The method of claim 1, further comprising the step of providing a protective film over the individual slabs after the laminating step.

10. The method of claim 1, wherein the step of applying a conductive layer further comprises printing the conductive layer onto at least one of the first outer surface or the second outer surface of the ceramic substrate.

11. A roll of electronic components, comprising:
a plurality of electronic components, each of the electronic components comprising a ceramic substrate; and
a strip of polymeric carrier, the plurality of electronic components adhered to a surface of the strip of polymeric carrier;
wherein each ceramic substrate has a first thickness and a first flexural rigidity and the strip of polymeric carrier has a second thickness and a second flexural rigidity;
wherein the first thickness is less than the second thickness; and
wherein the first flexural rigidity is at least five times the second flexural rigidity.

12. The roll of electronic components of claim 11, wherein the ceramic substrate comprises at least one of alumina, zirconia, titanates, or ferrites.

13. The roll of electronic components of claim 11, wherein the first thickness of each ceramic substrate is less than 200 μm.

14. The roll of electronic components of claim 11, wherein the second thickness of the strip of polymeric carrier is less than 125 μm.

15. The roll of electronic components of claim 11, wherein the plurality of electronic components are adhered to the surface of the strip of polymeric carrier at an adhesion strength of no more than 0.5 N/cm as measured according to ASTM D6862.
